(19) United States
(12) Patent Application Publication
(10) Pub. No.: US 2023/0095545 A1
(43) Pub. Date: Mar. 30, 2023

(54) Semiconductor Packages and Methods for Manufacturing Thereof

(71) Applicant: Infineon Technologies AG, Neubiberg (DE)

(72) Inventors: Paul Armand Calo, Villach (AT); Thomas Bemmerl, Schwandorf (DE); Joo Ming Goa, Batu Pahat Johor (MY); Edward Myers, Unterhaching (DE); Wee Boon Tay, Krubong (MY); Stefan Macheiner, Kissing (DE); Markus Dinkel, Unterhaching (DE); Andreas Piller, Unterhaching (DE)

(21) Appl. No.: 17/950,662

(22) Filed: Sep. 22, 2022

(30) Foreign Application Priority Data
Sep. 24, 2021 (DE) 102021124744.6
Aug. 18, 2022 (DE) 102022120924.5

(51) Int. Cl. H01L 23/495; H01L 23/498; H01L 21/48; H01L 23/31

(52) U.S. Cl. CPC H01L 23/49582; H01L 23/49805; H01L 23/49861; H01L 23/49562; H01L 23/49565; H01L 23/49575; H01L 21/4842; H01L 23/315; H01L 21/4839

(57) ABSTRACT

A semiconductor package includes a leadframe including a diepad and a first row of leads, wherein at least one lead of the first row of leads is physically separated from the diepad by a gap. The semiconductor package further includes a semiconductor component arranged on the leadframe. The semiconductor package further includes an encapsulation material encapsulating the leadframe and the semiconductor component, wherein the encapsulation material includes a bottom surface arranged at a bottom surface of the semiconductor package, a top surface and a side surface extending from the bottom surface to the top surface. A side surface of at least one lead of the first row of leads is flush with the side surface of the encapsulation material. The flush side surface of the at least one lead is covered by an electroplated metal coating.

### TECHNICAL FIELD

The present disclosure relates to semiconductor packages. In addition, the present disclosure relates to methods for manufacturing semiconductor packages.

### BACKGROUND

In semiconductor packaging, one or more components of a semiconductor device may be encapsulated by an encapsulation material for securing the components against external influences, such as e.g. moisture or mechanical impact. When manufacturing semiconductor packages, multiple method acts may be performed, wherein each additional act of the manufacturing process may result in increased complexity and costs. Manufacturers and developers of semiconductor packages are constantly striving to improve their products. In particular, it may be desirable to provide manufacturing methods with a reduced number of required method acts in order to provide cost-efficient semiconductor packages.

### SUMMARY

An aspect of the present invention relates to a method. The method comprises providing a leadframe strip, wherein the leadframe strip comprises multiple leadframes. Each leadframe of the multiple leadframes comprises a diepad and a first row of leads arranged at a first side of the diepad. At least one lead of the first row of leads is physically separated from the diepad by a gap. The method further comprises arranging semiconductor components on the leadframes. The method further comprises encapsulating the leadframes and the semiconductor components with an encapsulation material. The method further comprises forming first gaps in the encapsulation material, wherein the first gaps extend through the encapsulation material in a direction perpendicular to a main surface of the leadframe strip. After forming the first gaps leads of the first rows of leads are at least partly exposed from the encapsulation material. The method further comprises forming a metal coating on the exposed leads based on an electroplating process. The method further comprises forming second gaps in the encapsulation material, wherein the second gaps intersect with the first gaps and extend through the encapsulation material in the direction perpendicular to the main surface of the leadframe strip.

An aspect of the present invention relates to a semiconductor package. The semiconductor package comprises a leadframe comprising a diepad and a first row of leads, wherein at least one lead of the first row of leads is physically separated from the diepad by a gap. The semiconductor package further comprises a semiconductor component arranged on the leadframe. The semiconductor package further comprises an encapsulation material encapsulating the leadframe and the semiconductor component. The encapsulation material comprises a bottom surface arranged at a bottom surface of the semiconductor package, a top surface and a side surface extending from the bottom surface to the top surface. A side surface of at least one lead of the first row of leads is flush with the side surface of the encapsulation material. The flush side surface of the at least one lead is covered by an electroplated metal coating.

### BRIEF DESCRIPTION OF THE DRAWINGS

The accompanying drawings are included to provide a further understanding of aspects. The drawings illustrate aspects and together with the description serve to explain principles of aspects. Other aspects and many of the intended advantages of aspects will be readily appreciated as they become better understood by reference to the following detailed description. The elements of the drawings are not necessarily to scale relative to each other. Like reference signs may designate corresponding similar parts.

FIG. 1 schematically illustrates a perspective view of a semiconductor package 100 in accordance with the disclosure.

FIG. 2 schematically illustrates a cross-sectional side view of a semiconductor package 200 in accordance with the disclosure mounted on a printed circuit board.

FIG. 3 illustrates a flowchart of a method for manufacturing a semiconductor package in accordance with the disclosure.

FIG. 4 includes FIGS. 4A to 4C schematically illustrating top views of a method for manufacturing semiconductor packages in accordance with the disclosure.

FIG. 5 includes FIGS. 5A and 5B illustrating a formation of gaps in an encapsulation material based on a sawing act.

FIG. 6 schematically illustrates a bottom view of semiconductor packages 600 manufactured in accordance with the disclosure.

FIG. 7 schematically illustrates a bottom view of semiconductor packages 700 manufactured in accordance with the disclosure.

FIG. 8 schematically illustrates a bottom view of semiconductor packages 800 manufactured in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

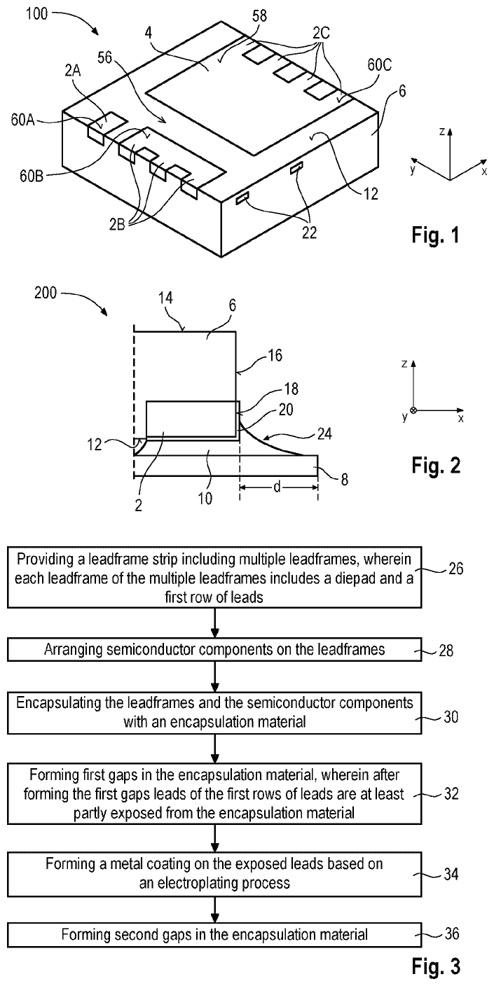

FIGS. 1 and 2 schematically illustrate semiconductor packages 100 and 200 in accordance with the disclosure. One or more design features of the semiconductor packages 100 and 200 may result from specific method acts used in the manufacturing of the semiconductor packages. Exemplary methods for manufacturing semiconductor packages in accordance with the disclosure will be described later on.

The semiconductor package 100 of FIG. 1 may include a leadframe. In the example of FIG. 1, the leadframe may include one or more leads 2A, 2B, 2C and a diepad 4. The leads 2A and 2B may form a first row of leads arranged at a first side of the diepad 4. At least one lead of the first row of leads 2A, 2B may be physically separated from the diepad 4 by a gap 56. In the illustrated example, each of the leads 2A and 2B may be separated from the diepad 4 by the gap 56. The leads 2C may form a second row of leads arranged at a second side of the diepad 4 opposite to the first side of the diepad 4. At least one lead of the second row of leads 2C may be directly physically connected to the diepad 4. In the illustrated example, each of the leads 2C may be directly physically connected to the diepad 4. In particular, the second row of leads and the diepad 4 may be formed as a single piece.

The semiconductor package 100 may further include one or more semiconductor components that may be arranged on the diepad 4. The leadframe and the semiconductor components may be at least partly encapsulated by an encapsulation material 6. In the illustrated perspective of FIG. 1, the semiconductor components may be arranged on the bottom surface of the diepad 4 and may be covered by the encapsulation material 6. Accordingly, in the illustrated example, the semiconductor components may remain invisible to a viewer. Note that the gap 56 may be filled with the encapsulation material 6.

The bottom surface of the semiconductor package 100 may be formed by the bottom surface 12 of the encapsulation material 6, the bottom surface 58 of the diepad 4 and the bottom surfaces 60A to 60C of the leads 2A to 2C. In particular, the bottom surface 12 of the encapsulation material 6, the bottom surface 58 of the diepad 4 and the bottom surfaces 60A to 60C of the leads 2A to 2C may be arranged in a common plane (or may be coplanar or may be at the same level).

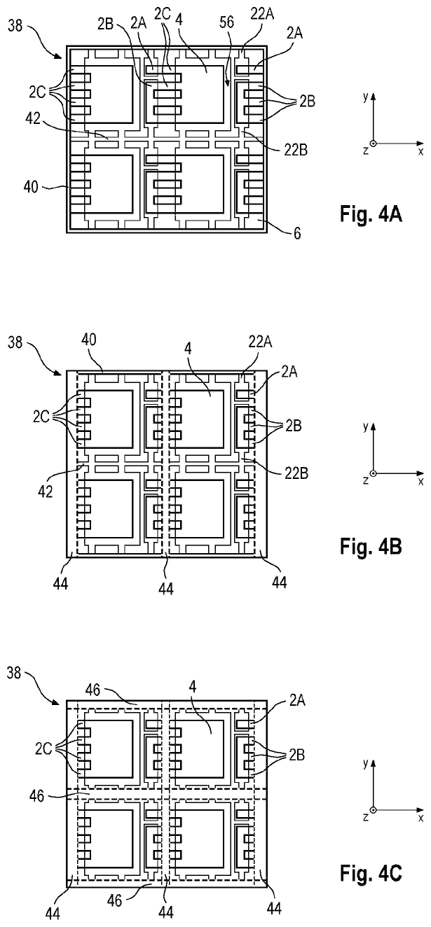

The bottom surface of the semiconductor package 100 may be (in particular completely) planar (or flat). In this regard, the bottom surface of the semiconductor package 100 may not necessarily include any groove, recess, indentation, trench, or the like. In particular the bottom surface of the semiconductor package 100 may be free of any grooves, recesses, indentations, trenches, or the like, between the bottom surface 58 of the diepad 4 and the bottom surfaces 60A, 60B of the first row of leads 2A, 2B. The planar structure of the bottom surface of the semiconductor package 100 may particularly result from a specific type of method used for manufacturing the semiconductor package 100. An exemplary method is, for example, described in connection with FIG. 4.

The one or more semiconductor components may e.g. include or may correspond to a semiconductor chip of arbitrary type. In the non-limiting example of FIG. 1, a semiconductor component may correspond to a power semiconductor, such as e.g. a power transistor or a power MOSFET (Metal Oxide Semiconductor Field Effect Transistor), including a gate contact, a source contact and a drain contact. The gate contact may be electrically connected to a first lead 2A, the source contact may be electrically connected to second leads 2B, and the drain contact may be electrically connected to third leads 2C and to the diepad 4. That is, the contacts of the power transistor may be electrically accessible from outside of the encapsulation material 6 via the leads 2A, 2B, 2C and the diepad 4. In the example of FIG. 1, all leads of the semiconductor package 100 may be arranged at two opposite side surfaces of the encapsulation material 6. In particular, the semiconductor package 100 may correspond to a flat no-leads package.

The leadframe may be fabricated from metals and/or metal alloys, in particular at least one of copper, copper alloys, nickel, iron nickel, etc. The encapsulation material 6 may include at least one of the following materials: epoxy, filled epoxy, glass fiber filled epoxy, imide, thermoplast, thermoset polymer, polymer blend, etc. In particular, the encapsulation material 6 may be formed from a mold compound. The encapsulation material 6 may be configured to protect encapsulated components of the semiconductor package 100 against external influences, such as e.g. moisture or mechanical impact.

The semiconductor package 200 of FIG. 2 may include some or all of the features of the semiconductor package 100 of FIG. 1. In particular, the semiconductor package 200 may correspond to the semiconductor package 100 of FIG. 1, but turned upside down. FIG. 2 only shows the right part of the semiconductor package 200, while the left part of the semiconductor package 200 is not illustrated for the sake of simplicity.

The semiconductor package 200 may be mounted on a printed circuit board 8. In this regard, a solder material 10 may provide a mechanical and electrical connection between leads 2 of the semiconductor package 200 and the printed circuit board 8. In the example of FIG. 2, only one lead 2 connected to the printed circuit board 8 is illustrated for the sake of simplicity. Referring back to FIG. 1, each of the leads 2A, 2B, 2C and the diepad 4 may be connected to the printed circuit board 8 by a solder material.

The encapsulation material 6 may include a bottom surface 12, a top surface 14 and a side surface 16 extending from the bottom surface 12 to the top surface 14. A side surface 18 of the lead 2 may be flush with the side surface 16 of the encapsulation material 6. That is, the side surfaces 16 and 18 may be arranged in a common plane. In a similar fashion, the bottom surface of the lead 2 and the bottom surface of the encapsulation material 6 may be flush. The flush side surface 18 of the lead 2 may be covered by an electroplated metal coating 20 which may at least partly protrude out of the common plane formed by the side surfaces 16 and 18. In the example of FIG. 2, the entire side surface 18 of the lead 2 may be flush with the side surface 16 of the encapsulation material 6. In addition, the entire side surface 18 of the lead 2 may be covered by the electroplated metal coating 20. It is to be noted that the electroplated metal coating 20 may also be arranged at least partly on the bottom surface of the lead 2.

A thickness of the metal coating 20 may e.g. be greater than about 4 micrometer, or greater than about 5 micrometer, or greater than about 6 micrometer, or greater than about 7 micrometer. In a more specific example, a thickness of the metal coating 20 may lie in a range from about 7 micrometer to about 10 micrometer. The metal coating 20 may be made of any suitable metal and/or metal alloy, such as e.g. tin, nickel or alloys thereof. In particular, the metal coating 20 may be manufactured based on an electroplating process. In this regard, the metal coating 20 may be devoid of gold.

Referring back to FIG. 1, each of the semiconductor packages 100 and 200 may include one or more tie bars 22 or portions thereof. The tie bars 22 and the leads 2A, 2B, 2C of the semiconductor packages 100 and 200 may be arranged at different side surfaces of the encapsulation material 6. In particular, a side surface of each tie bar 22 may be flush with a side surface of the encapsulation material 6. The side surface of the tie bar 22 may be exposed from (or uncovered by) the metal coating 20. In other words, the side surface of the tie bar 22 may be non-plated (or not plated). The tie bar 22 may be a part of the leadframe and may thus be made of a similar material. In particular, the materials of the tie bar 22 and the metal coating 20 may differ. In one specific example, the tie bar 22 may include or may be made of copper or a copper alloy while the metal coating 20 may include or may be made of tin or a tin alloy.

The semiconductor package 200 may be soldered to the printed circuit board 8 based on a reflow soldering process in one example. Here, a solder meniscus (or solder fillet) 24 may be formed by the solder material 10. Due to variations in characteristics of the soldering process and/or due to contaminations, the quality of the soldering joints between the leads 2 and respective contact pads of the printed circuit board 8 may vary. In order to assure an appropriate quality of the solder connection, the solder joints may be inspected after the solder process, for example based on a lead-tip inspection. Here, a visual inspection of the solder material 10 protruding from under the semiconductor package 200, when viewed in the (negative) z-direction, may be performed.

In order to perform an appropriate lead tip inspection, the solder meniscus 24 may need to sufficiently extend over the edge of the encapsulation material 6 by a distance “d” when viewed in the z-direction. For example, the distance “d” may be greater than about 250 micrometer, or greater than about 300 micrometer, or greater than about 350 micrometer, or greater than about 400 micrometer. In the example of FIG. 2, a lead tip inspection feature may be provided by the metal coating 20. The peripheral surfaces of the metal coating 20 may provide an (in particular fully) wettable surface for a reflow soldering process that is to be performed. In this regard, an arrangement of the metal coating 20 over the entire side surface 18 of the lead 2 may provide for an optimal formation of the solder meniscus 24 such that an appropriate lead tip inspection may be performed.

In other semiconductor packages (not illustrated herein), a lead tip inspection feature may be provided by forming a step in the leads that are to be connected to the printed circuit board. Referring to FIG. 2, such step may e.g. be arranged in the lower right part of the lead 2. In order to form such step, method acts of mounting (on a tape or a foil), step cutting and demounting may be required. The formed step may then be plated by a metal coating providing a wettable surface for reflow soldering. However, at least a portion of the lead tip may remain non-wettable. In some cases, a maximum of only about 50 percent of the lead height can be wetted. In the case of the semiconductor package 200 of FIG. 2, an additional step as described may not be required. An appropriate lead tip inspection feature may already be provided by forming the metal coating 20 over substantially the entire side surface of the lead 2. Accordingly, when manufacturing a semiconductor package in accordance with the disclosure, the additional method acts of mounting, step cutting and demounting may be omitted such that production costs of the semiconductor package may be lowered.

FIG. 3 illustrates a flowchart of a method for manufacturing one or more semiconductor packages in accordance with the disclosure. For example, the method may be used for manufacturing any of the semiconductor packages 100 and 200 described in connection with FIGS. 1 and 2. The method of FIG. 3 is described in a general manner in order to qualitatively specify aspects of the disclosure. It is understood that the method may include further aspects. For example, the method may be extended by any of the aspects described in connection with other examples in accordance with the disclosure.

At 26, a leadframe strip may be provided, wherein the leadframe strip may include multiple leadframes. Each leadframe of the multiple leadframes may include a diepad and a first row of leads arranged at a first side of the diepad. At least one lead of the first row of leads may be physically separated from the diepad by a gap. At 28, semiconductor components may be arranged on the leadframes. At 30, the leadframes and the semiconductor components may be encapsulated by an encapsulation material. At 32, first gaps may be formed in the encapsulation material, wherein the first gaps may (in particular fully) extend through the encapsulation material in a direction perpendicular to a main surface of the leadframe strip. After forming the first gaps leads of the first rows of leads may be at least partly exposed (or uncovered) from the encapsulation material. At 34, a metal coating may be formed on the exposed (or uncovered) leads based on an electroplating process. At 36, second gaps may be formed in the encapsulation material, wherein the second gaps may intersect with the first gaps and may (in particular fully) extend through the encapsulation material in the direction perpendicular to the main surface of the leadframe strip.

FIGS. 4A to 4C illustrate a method for manufacturing one or more semiconductor packages in accordance with the disclosure. For example, the method of FIG. 4 may be used for manufacturing any of the semiconductor packages 100 and 200 described in connection with FIGS. 1 and 2. The method of FIG. 4 may include some or all of the features of the method of FIG. 3.

In FIG. 4A, one or more method acts may be performed. Referring back to FIG. 3, the method act of FIG. 4A may be associated with the method acts 26, 28 and 30. In FIG. 4A, a leadframe strip 38 including multiple leadframes (or unit leadframes) may be provided. In a non-limiting example, the leadframes of the leadframe strip 38 may correspond to half-etched leadframes. The leadframe strip 38 and its main surface may be substantially arranged in the x-y-plane. The leadframe strip 38 may be structured such that multiple diepads and multiple leads of the individual (unit) leadframes may be formed. For example, the leadframe strip 38 may be fabricated by structuring a metal sheet based on one or more of mechanical sawing, a laser beam, cutting, stamping, milling, etching, etc. The diepads and the leads of the leadframe strip 38 may be mechanically and electrically connected to each other. In particular, the diepads and the leads may be made from one piece before the individual leadframes are separated from each other later on.

The leadframe strip 38 may include a peripheral frame 40 and at least one support rail 42. In the example of FIG. 4A, the leadframe strip 38 may include exemplary numbers of one support rail 42 and four leadframes. In further examples, the leadframe strip 38 may include an arbitrary other (in particular higher) number of support rails and leadframes. The individual leadframes may be arranged between the peripheral frame 40 and the support rail 42. For example, each of the leadframes may include a diepad 4 and leads 2A, 2B, 2C as previously shown and described in connection with FIG. 1.

The leads 2A and 2B may form a first row of leads arranged at a first side of the respective diepad 4. In the illustrated example, the first row of leads 2A, 2B may be arranged at a right side of the respective diepad 4. At least one lead of the first row of leads 2A, 2B may be physically separated from the diepad 4 by a gap 56. For example, the gap 56 may correspond to an air gap. Accordingly, not all leads of a respective leadframe may be connected to the diepad 4. In the illustrated example, each of the leads 2A and 2B may be separated from the diepad 4 by the gap 56.

The leads 2C may form a second row of leads arranged at a second side of the diepad 4 opposite to the first side of the diepad 4. In the illustrated example, the second row of leads 2C may be arranged at the left side of the respective diepad 4. At least one lead of the second row of leads 2C may be directly physically connected to the diepad 4. In the illustrated example, each of the leads 2C may be directly physically connected to the diepad 4. In particular, the second row of leads 2C and the diepad 4 may be formed as a single piece.

As can e.g. be seen from the upper two (unit) leadframes of the leadframe strip 38, the first row of leads 2A, 2B of the left leadframe may be directly physically connected to the second row of leads 2C of the right leadframe neighboring the left leadframe. The corresponding leads 2A, 2B of the left leadframe and the corresponding leads 2C of the right leadframe may be connected as a single piece of metal. More particular, the lead 2A on the left and the uppermost lead of the leads 2C on the right may be directly physically connected and may form one continuous piece. And, in a similar fashion, the three leads 2B on the left and the remaining three leads 2C on the right may be directly physically connected respectively and may form three continuous pieces.

At least some of the leads of the leadframe strip 38 may be connected to at least one of the peripheral frame 40 or the support rail 42. For example, the first lead 2A may be mechanically and electrically connected to the peripheral frame 40 via a tie bar 22A. In a similar fashion, the second leads 2B may be mechanically and electrically connected to the support rail 42 via a tie bar 22B. The tie bars of the leadframe strip 38 may be arranged along the support rail 42 and along portions of the peripheral frame 40 extending in the x-direction. It is to be noted that the leadframe strip 38 may also include leads which may not be (directly) connected to the peripheral frame 40 or to the support rail 42. For example, the third leads 2C may be directly connected to a respective diepad 4.

In a further method act associated with FIG. 4A, semiconductor components may be arranged on the leadframes. In the example of FIG. 4A, power transistor chips, such as e.g. power MOSFETs, may be arranged on the diepads 4. Each of the power transistor chips may include a gate electrode, a source electrode and a drain electrode. In case of a vertical power transistor chip, the drain electrode may be arranged at a first main surface of the power transistor chip while the gate electrode and the source electrode may be arranged on a second main surface of the power transistor chip arranged opposite to the first main surface. The drain electrode may be electrically connected to the diepad 4 and to the third leads 2C when placing the first main surface of the power transistor chip on the diepad 4. In addition, the gate electrode may be electrically connected to the first lead 2A, and the source electrode may be electrically connected to the second leads 2B. In this regard, an electrical connection may be provided by means of electrical connection elements including one or more of e.g. bond wires, ribbons, clips, etc.

In a further method act associated with FIG. 4A, the leadframes and the semiconductor components may be encapsulated by an encapsulation material 6. Various techniques may be used for encapsulating the arrangement, for example at least one of compression molding, injection molding, powder molding, liquid molding, map molding, laminating, etc. It is to be noted that, in practice, the structures and components shown in FIG. 4A may be covered by the encapsulation material 6 and may thus be invisible to a viewer. During the encapsulation act, the gap 56 may be filled with the encapsulation material 6. As previously described, the first row leads 2A, 2B and the second row of leads 2C may be directly physically connected. Accordingly, after performing the encapsulation act, there may be no encapsulation material 6 arranged between the first row leads 2A, 2B and the second row of leads 2C.

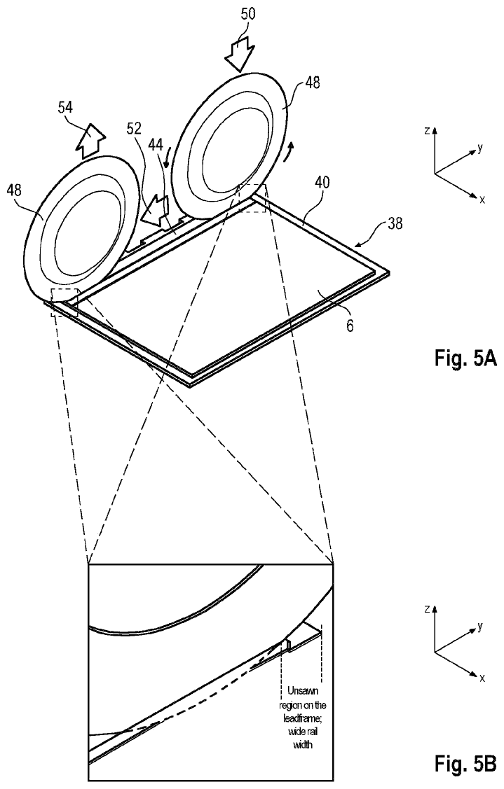

In FIG. 4B, one or more method acts may be performed. Referring back to FIG. 3, the method act of FIG. 4B may be associated with the method acts 32 and 34. In FIG. 4B, first gaps 44 may be formed in the encapsulation material 6. The first gaps 44 may be formed between the individual leadframes of the leadframe strip 38 and may substantially extend in the y-direction, i.e. substantially perpendicular to the support rail 42. In FIG. 4B, the first gaps 44 are indicated by vertical dashed lines. For example, forming the first gaps 44 may include at least one of sawing the encapsulation material 6 or cutting the encapsulation material 6. An example of forming the first gaps 44 based on a sawing act is shown and described in connection with FIGS. 5A and 5B.

The first gaps 44 may (in particular fully) extend through the encapsulation material 6 in the z-direction, i.e. perpendicular to the main surface of the leadframe strip 38. In particular, the encapsulation material 6 and the leadframe strip 38 may be completely separated by forming the first gaps 44 in the y-direction. Accordingly, after forming the first gaps 44, the leads of the leadframes arranged along the first gaps 44 may become exposed from the encapsulation material 6. As already shown and described in connection with FIG. 2, the side surfaces of the exposed leads and the side surface of the encapsulation material 6 may be flush. Since, in the example of FIG. 4B, all leads of the leadframes may be arranged along the first gaps 44 in the y-direction, all of the leads may become exposed from the encapsulation material 6.

As previously described in connection with FIG. 4A, the first row leads 2A, 2B and the second row of leads 2C may be directly physically connected before forming the first gaps 44. During forming the first gaps 44, the first row of leads 2A, 2B of a first leadframe may be physically separated from the second row of leads 2C of a second leadframe neighboring the first leadframe. For example, the leads 2A, 2B of the leadframe on the top left may be physically separated from the leads 2C of the leadframe on the top right. The first gaps 44 may extend through the encapsulation material 6 and the material (or metal material) of the physically connected leads. Afterwards, the side surfaces of the leads of the first row of leads 2A, 2B and the side surfaces of the leads of the second row of leads 2C may be exposed.

A dimension of the first gaps 44 in the y-direction may be smaller than a dimension of the encapsulation material 6 in the y-direction. That is, the encapsulation material 6 may not be completely separated by the first gaps 44 along the y-direction. In a similar fashion, the peripheral frame 40 may not necessarily be affected or separated by the first gaps 44. Regions of the leadframe strip 38 and the encapsulation material 6 which may remain unaffected by the first gaps 44 are shown and described in connection with FIGS. 5A and 5B.

In a further method act performed in connection with FIG. 4B, a metal coating may be formed on the exposed leads based on electroplating. Before performing the electroplating process, a deflash act may be performed for removing unwanted mold compound residues from leadframe surfaces that are to be electroplated. During the electroplating process, the exposed lead tips may be fully exposed to an employed electroplating chemical. As can be seen from FIG. 4B, at least some of the leads of the leadframes may still be connected to at least one of the peripheral frame 40 or to the support rail 42 after forming the first gaps 44. For example, the first lead 2A may still be connected to the upper part of the peripheral frame 40 via the tie bar 22A. In a similar fashion, the second leads 2B may still be connected to the support rail 42 via the tie bar 22B. The third leads 2C may be connected to at least one of the peripheral frame 40 or the support rail 42 via the respective diepad 4. When performing the electroplating process, the tie bars 22 may provide an electric connection to the leads for applying an electric potential. After performing the electroplating process, a metal coating 20 may have been formed on the leads, as e.g. shown and described in connection with FIG. 2.

In FIG. 4C, one or more method acts may be performed. Referring back to FIG. 3, the method act of FIG. 4C may be associated with the method act 36. In FIG. 4C, second gaps 46 may be formed in the encapsulation material 6. The second gaps 46 may be formed similar to the first gaps 44 such that comments made in connection with FIG. 4B may also hold true for FIG. 4C. The second gaps 46 may intersect with the first gaps 44 and may (in particular fully) extend through the encapsulation material 6 in the z-direction. The second gaps 46 may be formed between the individual leadframes of the leadframe strip 38. In the example of FIG. 4C, the second gaps 46 may substantially extend in the x-direction and may be arranged substantially vertical to the first gaps 44.

By forming the second gaps 46, the tie bars 22 of the leadframe strip 38 may be cut through and the leads of the individual leadframes may be separated from the peripheral frame 40 and from the support rail 42. Referring back to FIG. 1, the remaining portions of the tie bars 22 may be flush with the encapsulation material 6 afterwards. Multiple semiconductor packages may be obtained by forming the second gaps 46. For example, each of the singulated semiconductor packages may be similar to one of the semiconductor packages 100 and 200 of FIGS. 1 and 2. It is to be noted that, after forming the second gaps 46, the singulated semiconductor packages may still be arranged on a common tape or foil which may be removed later on.

Due to the gap 56 arranged between the diepad 4 and the leads 2A, 2B, there may be no need for any additional method act that separates the leads 2A and 2B from the diepad 4. In conventional methods for manufacturing semiconductor packages, additional method acts may be required for providing such separation. In particular, such additional method acts may be applied at the bottom surface of a respective semiconductor package, thereby leaving grooves or trenches in the bottom surface of the final product. In contrast to this, semiconductor packages in accordance with the disclosure may provide a planar bottom surface as previously described in connection with FIG. 1. In particular, the bottom surface of a semiconductor package manufactured based on a method in accordance with the disclosure may be free of grooves between a bottom surface of the diepad 4 and a bottom surface of the first row of leads 2A, 2B.

FIG. 5 includes FIGS. 5A and 5B illustrating a formation of gaps in an encapsulation material 6 based on a sawing (or jig-sawing) act. FIG. 5B shows an enlarged section of FIG. 5A. In FIG. 5A, a leadframe strip 38 may be provided. For example, the leadframe strip 38 may be similar to the leadframe strip 38 of FIG. 4. A rotating sawing blade 48 may be provided and may be lowered (see arrow 50) in order to cut into the encapsulation material 6. Here, the sawing blade 48 may be lowered in the (negative) z-direction until it may (in particular fully) penetrate through the encapsulation material 6 in the z-direction. As can be seen from the more detailed view of FIG. 5B, a portion of the leadframe strip 38 including the peripheral frame 40 may remain unaffected by the sawing blade 48.

The sawing blade 48 may then move along the (negative) y-direction (see arrow 52) and may saw through the encapsulation material 6 and the leadframe strip 38, thereby forming first gaps 44 as previously described in connection with FIG. 4B. When reaching the peripheral frame 40, a portion of the leadframe strip 38 may again remain unaffected by the sawing blade 48 as already mentioned in connection with FIG. 5B. After forming the first gaps 44, the sawing blade 48 may be lifted up in the (positive) z-direction (see arrow 54). Note that the peripheral frame 40 may be provided with a wider rail on either side in order to provide a robust support for the leadframe strip 38 during method acts performed afterwards, such as e.g. an electroplating process.

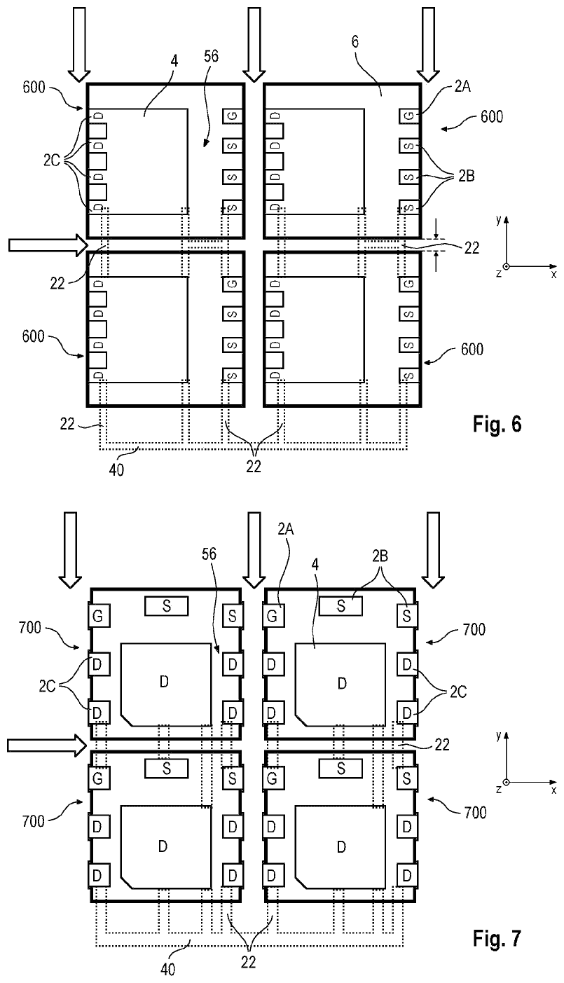

FIG. 6 illustrates an exemplary number of four semiconductor packages 600 manufactured in accordance with the disclosure. Each of the semiconductor packages 600 may be similar to the semiconductor packages 100 and 200 of FIGS. 1 and 2. A semiconductor package 600 may include a gate lead providing a gate electrode 2A, source leads 2B providing a source electrode, as well as a diepad 4 and leads 2C providing a drain electrode. Vertical arrows indicate a method act that may have been performed for forming first gaps, thereby separating the individual semiconductor packages in the vertical direction. In a similar fashion, horizontal arrows indicate a method act that may have been performed for forming second gaps intersecting the first gaps, thereby singulating the arrangement into multiple semiconductor packages 600. For illustrative purposes, dotted lines of FIG. 6 further illustrate a portion of a peripheral frame 40 and tie bars 22 that may have been employed during the fabrication of the semiconductor packages 600. In one embodiment of FIG. 6, the three source pads 2B may be a fused lead, which means they are connected via a common metal piece, and then further connecting to a tie bar 22 or the peripheral frame 40. At the same time, the gate pad 2A connects to the peripheral frame 40 via a tie bar 22, as shown in FIG. 4A. Further, two die pads 4 of an upper row and a bottom row can connect to the support rail 42 via tie bars 22, as shown in FIG. 4A.

In each of the manufactured semiconductor packages 600, the gate lead 2A (see G) and the source leads 2B (see S) may form a first row of leads arranged at the right side of the diepad 4. Each lead of this first row of leads 2A, 2B may be physically separated from the diepad 4 by a gap 56. Furthermore, the drain leads 2C (see D) may form a second row of leads arranged at the left side of the diepad 4. Each of the drain leads 2C may be directly physically connected to the diepad 4. Note that before forming the first gaps (as indicated by the vertical arrow) the gate lead 2A of the respective left leadframe may have been directly physically connected to the uppermost drain pad 2C of the respective right leadframe. In addition, the three source leads 2B of the respective left leadframe may have been directly physically connected to the remaining three drain leads 2C of the respective right leadframe. The leads may have been physically separated by forming the first gaps.

FIG. 7 illustrates an exemplary number of four semiconductor packages 700 manufactured in accordance with the disclosure. The semiconductor packages 700 may be similar to the semiconductor packages 600 of FIG. 6. In contrast to FIG. 6, the semiconductor packages 700 may have a different arrangement and design of the gate electrode, source electrode and drain electrode. In particular, each of the semiconductor packages 700 may include a gate electrode formed by one lead 2A, a source electrode formed by two leads 2B, and a drain electrode formed by an exemplary number of four leads 2C. Similar to FIG. 6, previously performed acts of forming first and second gaps are indicated by vertical and horizontal arrows, respectively. In addition, portions of a peripheral frame 40 and tie bars 22 that may have been employed during the manufacturing of the semiconductor packages 700 are indicated by dotted lines.

In each of the manufactured semiconductor packages 700, one of the source leads 2B (see S) and two of the drain leads 2C (see D) may form a first row of leads arranged at the right side of the diepad 4. The source lead 2B may be physically separated from the diepad 4 by a gap 56, while the two drain leads 2C may be physically connected to the diepad 4. In this connection it is to be noted that the leadframe of the semiconductor package 700 may correspond to a half-etched leadframe. Therefore, in the bottom view of FIG. 7, the direct physical connection between the drain leads 2C and the diepad 4 may be covered by the encapsulation material 6 and may therefore not be visible to a viewer. However, the direct physical connection between the drain leads 2C and the diepad 4 is indicated by labelling each of the diepads 4 with a “D”.

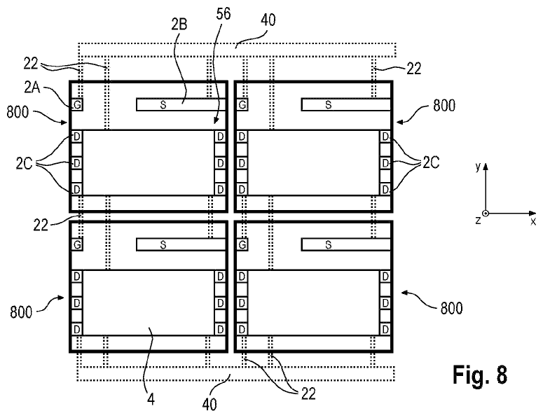

Furthermore, in each of the semiconductor packages 700, the gate lead 2A (see G) and the other two of the drain leads 2C (see D) may form a second row of leads arranged at the left side of the diepad 4. Again, a direct physical connection between the two drain leads 2C and the diepad 4 may be not visible due to the chosen perspective. Note that before forming the first gaps (as indicated by the vertical arrow) the source lead 2B of the respective left leadframe may have been directly physically connected to the gate lead 2A of the respective right leadframe. In addition, the two drain leads 2C of the respective left leadframe may have been directly physically connected to the two drain leads 2C of the respective right leadframe. The leads may have been physically separated by forming the first gaps. In one embodiment of FIG. 7, since the gate pad 2A and the source pads 2B do not directly connect to the diepads 4, therefore they are respectively connecting to the peripheral frame 40 or the supporting rail 42 via tie bars, which are not shown in FIG. 8. But a skilled person should understand this based on the embodiments of FIGS. 4 to 6. The general purpose is to make sure each pad connects to the peripheral frame 40 or the support rail 42 during the electroplating process.

FIG. 8 illustrates an exemplary number of four semiconductor packages 800 manufactured in accordance with the disclosure. The semiconductor packages 800 may be similar to the semiconductor packages 600 and 700 of FIGS. 6 and 7. In contrast to FIGS. 6 and 7, the semiconductor packages 800 may have a different arrangement and design of the gate electrode, source electrode and drain electrode. Each of the semiconductor packages 800 may include a gate electrode formed by one lead 2A, a source electrode formed by one bar-shaped lead 2B, and a drain electrode formed by an exemplary number of six leads 2C. Similar to FIGS. 6 and 7, portions of a peripheral frame 40 and tie bars 22 that may have been employed during the manufacturing of the semiconductor packages 800 are indicated by dotted lines.

In each of the manufactured semiconductor packages 800, the source lead 2B (see S) and three of the drain leads 2C (see D) may form a first row of leads arranged at the right side of the diepad 4. This source lead 2B may be physically separated from the diepad 4 by a gap 56. Furthermore, the gate lead 2A (see G) and the three other drain leads 2C (see D) may form a second row of leads arranged at the left side of the diepad 4. The drain leads 2C may be directly physically connected to the diepad 4. Note that before forming vertical gaps the source lead 2B of the respective left leadframe may have been directly physically connected to the gate lead 2A of the respective right leadframe. In addition, the three drain leads 2C of the respective left leadframe may have been directly physically connected to the three drain leads 2C of the respective right leadframe. The leads may have been physically separated by forming the vertical gaps.

### EXAMPLES

In the following, semiconductor packages and methods for manufacturing thereof in accordance with the disclosure will be explained by means of examples.

Example 1 is a method, comprising: providing a leadframe strip, wherein the leadframe strip comprises multiple leadframes, wherein each leadframe of the multiple leadframes comprises a diepad and a first row of leads arranged at a first side of the diepad, wherein at least one lead of the first row of leads is physically separated from the diepad by a gap; arranging semiconductor components on the leadframes; encapsulating the leadframes and the semiconductor components with an encapsulation material; forming first gaps in the encapsulation material, wherein the first gaps extend through the encapsulation material in a direction perpendicular to a main surface of the leadframe strip, wherein after forming the first gaps leads of the first rows of leads are at least partly exposed from the encapsulation material; forming a metal coating on the exposed leads based on an electroplating process; and forming second gaps in the encapsulation material, wherein the second gaps intersect with the first gaps and extend through the encapsulation material in the direction perpendicular to the main surface of the leadframe strip.

Example 2 is a method according to Example 1, wherein each leadframe of the multiple leadframes further comprises a second row of leads arranged at a second side of the diepad opposite to the first side of the diepad.

Example 3 is a method according to Example 2, wherein at least one lead of the second row of leads is directly physically connected to the diepad.

Example 4 is a method according to Example 2 or 3, wherein, before forming the first gaps, the first row of leads of a first leadframe of the multiple leadframes is physically connected to the second row of leads of a second leadframe of the multiple leadframes neighboring the first leadframe.

Example 5 is a method according to Example 4, wherein, before forming the first gaps, there is no encapsulation material arranged between the first row of leads of the first leadframe and the second row of leads of the second leadframe.

Example 6 is a method according to Example 4 or 5, wherein, during forming the first gaps, the first row of leads of the first leadframe is physically separated from the second row of leads of the second leadframe.

Example 7 is a method according to one of Examples 2 to 6, wherein each of the semiconductor components comprises a drain contact, a gate contact and a source contact, wherein the method further comprises: electrically coupling at least one of the gate contact or the source contact of a respective semiconductor component with the first row of leads of the respective leadframe on which the respective semiconductor component is arranged, and electrically coupling the drain contact of the respective semiconductor component to the second row of leads of the respective leadframe.

Example 8 is a method according to one of the preceding Examples, wherein multiple singulated semiconductor packages are obtained by forming the second gaps.

Example 9 is a method according to one of the preceding Examples, wherein: the leadframe strip comprises a peripheral frame and at least one support rail, and at least some of the leads of the leadframes are connected to at least one of the peripheral frame or the at least one support rail.

Example 10 is a method according to Example 9, wherein the at least some of the leads of the leadframes are still connected to at least one of the peripheral frame or the at least one support rail after forming the first gaps.

Example 11 is a method according to Example 9 or 10, wherein tie bars are used as an electric connection to the at least some of the leads during the electroplating process.

Example 12 is a method according to one of the preceding Examples, wherein the first gaps are formed between the leadframes and extend in a first direction, wherein a dimension of the first gaps in the first direction is smaller than a dimension of the encapsulation material in the first direction.

Example 13 is a method according to Example 12, wherein the first direction is substantially perpendicular to the at least one support rail.

Example 14 is a method according to one of the preceding Examples, wherein all leads of the leadframes are exposed by forming the first gaps.

Example 15 is a method according to one of Examples 12 to 14, wherein the second gaps are formed between the leadframes and extend in a second direction substantially perpendicular to the first direction.

Example 16 is a method according to one of Examples 9 to 15, wherein the leads are separated from the peripheral frame and the at least one support rail by forming the second gaps.

Example 17 is a semiconductor package, comprising: a leadframe comprising a diepad and a first row of leads, wherein at least one lead of the first row of leads is physically separated from the diepad by a gap; a semiconductor component arranged on the leadframe; and an encapsulation material encapsulating the leadframe and the semiconductor component, wherein the encapsulation material comprises a bottom surface arranged at a bottom surface of the semiconductor package, a top surface and a side surface extending from the bottom surface to the top surface, wherein a side surface of at least one lead of the first row of leads is flush with the side surface of the encapsulation material, and wherein the flush side surface of the at least one lead is covered by an electroplated metal coating.

Example 18 is a semiconductor package according to Example 17, wherein the bottom surface of the semiconductor package is planar.

Example 19 is a semiconductor package according to Example 17 or 18, wherein the bottom surface of the encapsulation material, a bottom surface of the diepad and a bottom surface of the at least one lead are arranged in a common plane.

Example 20 is a semiconductor package according to one of Examples 17 to 19, wherein the bottom surface of the semiconductor package is free of grooves between a bottom surface of the diepad and a bottom surface of the first row of leads.

Example 21 is a semiconductor package according to one of Examples 17 to 20, wherein the entire side surface of the at least one lead is flush with the side surface of the encapsulation material.

Example 22 is a semiconductor package according to one of Examples 17 to 21, wherein the entire side surface of the at least one lead is covered by the electroplated metal coating.

Example 23 is a semiconductor package according to one of Examples 17 to 22, wherein a thickness of the metal coating is greater than 4 micrometers.

Example 24 is a semiconductor package according to one of Examples 17 to 23, wherein the metal coating is devoid of gold.

Example 25 is a semiconductor package according to one of Examples 17 to 24, wherein: the leadframe further comprises a portion of a tie bar, and a side surface of the portion of the tie bar is flush with a side surface of the encapsulation material.

Example 26 is a semiconductor package according to Example 25, wherein the side surface of the tie bar is uncovered by a metal coating.

Example 27 is a semiconductor package according to one of Examples 17 to 26, wherein the semiconductor package is a flat no-leads package.

As employed in this specification, the terms “connected”, “coupled”, “electrically connected”, and/or “electrically coupled” may not necessarily mean that elements must be directly connected or coupled together. Intervening elements may be provided between the “connected”, “coupled”, “electrically connected”, or “electrically coupled” elements.

Further, the word “over” used with regard to e.g. a material layer formed or located “over” a surface of an object may be used herein to mean that the material layer may be located (e.g. formed, deposited, etc.) “directly on”, e.g. in direct contact with, the implied surface. The word “over” used with regard to e.g. a material layer formed or located “over” a surface may also be used herein to mean that the material layer may be located (e.g. formed, deposited, etc.) “indirectly on” the implied surface with e.g. one or multiple additional layers being arranged between the implied surface and the material layer.

Furthermore, to the extent that the terms “having”, “containing”, “including”, “with”, or variants thereof are used in either the detailed description or the claims, such terms are intended to be inclusive in a manner similar to the term “comprising”. That is, as used herein, the terms “having”, “containing”, “including”, “with”, “comprising”, and the like are open-ended terms that indicate the presence of stated elements or features, but do not preclude additional elements or features. The articles “a”, “an”, and “the” are intended to include the plural as well as the singular, unless the context clearly indicates otherwise.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or multiple” unless specified otherwise or clear from context to be directed to a singular form. Also, at least one of A and B or the like generally means A or B or both A and B.

Devices and methods for manufacturing devices are described herein. Comments made in connection with a described device may also hold true for a corresponding method and vice versa. For example, if a specific component of a device is described, a corresponding method for manufacturing the device may include an act of providing the component in a suitable manner, even if such act is not explicitly described or illustrated in the figures.

Although the disclosure has been shown and described with respect to one or multiple implementations, equivalent alterations and modifications will occur to others skilled in the art based at least in part upon a reading and understanding of this specification and the annexed drawings. The disclosure includes all such modifications and alterations and is limited only by the concept of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or multiple other features of the other implementations as may be desired and advantageous for any given or particular application.

1. A method, comprising:
providing a leadframe strip, wherein the leadframe strip comprises multiple leadframes, wherein each leadframe of the multiple leadframes comprises a diepad and a first row of leads arranged at a first side of the diepad, wherein at least one lead of the first row of leads is physically separated from the diepad by a gap;
arranging semiconductor components on the leadframes;
encapsulating the leadframes and the semiconductor components with an encapsulation material;
forming first gaps in the encapsulation material, wherein the first gaps extend through the encapsulation material in a direction perpendicular to a main surface of the leadframe strip, wherein after forming the first gaps leads of the first rows of leads are at least partly exposed from the encapsulation material;
forming a metal coating on the exposed leads based on an electroplating process; and
forming second gaps in the encapsulation material, wherein the second gaps intersect with the first gaps and extend through the encapsulation material in the direction perpendicular to the main surface of the leadframe strip.

2. The method of claim 1, wherein each leadframe of the multiple leadframes further comprises a second row of leads arranged at a second side of the diepad opposite to the first side of the diepad.

3. The method of claim 2, wherein at least one lead of the second row of leads is directly physically connected to the diepad.

4. The method of claim 2, wherein, before forming the first gaps, the first row of leads of a first leadframe of the multiple leadframes is physically connected to the second row of leads of a second leadframe of the multiple leadframes neighboring the first leadframe.

5. The method of claim 4, wherein, before forming the first gaps, there is no encapsulation material arranged between the first row of leads of the first leadframe and the second row of leads of the second leadframe.

6. The method of claim 4, wherein, during forming the first gaps, the first row of leads of the first leadframe is physically separated from the second row of leads of the second leadframe.

7. The method of claim 2, wherein each of the semiconductor components comprises a drain contact, a gate contact and a source contact, wherein the method further comprises:
electrically coupling at least one of the gate contact or the source contact of a respective semiconductor component with the first row of leads of the respective leadframe on which the respective semiconductor component is arranged, and
electrically coupling the drain contact of the respective semiconductor component to the second row of leads of the respective leadframe.

8. The method of claim 1, wherein multiple singulated semiconductor packages are obtained by forming the second gaps.

9. The method of claim 1, wherein:
the leadframe strip comprises a peripheral frame and at least one support rail, and
at least some of the leads of the leadframes are connected to at least one of the peripheral frame or the at least one support rail.

10. The method of claim 9, wherein the at least some of the leads of the leadframes are still connected to at least one of the peripheral frame or the at least one support rail after forming the first gaps.

11. The method of claim 9, wherein tie bars are used as an electric connection to the at least some of the leads during the electroplating process.

12. The method of claim 1, wherein the first gaps are formed between the leadframes and extend in a first direction, wherein a dimension of the first gaps in the first direction is smaller than a dimension of the encapsulation material in the first direction.

13. The method of claim 12, wherein the first direction is substantially perpendicular to the at least one support rail.

14. The method of claim 1, wherein all leads of the leadframes are exposed by forming the first gaps.

15. The method of claim 12, wherein the second gaps are formed between the leadframes and extend in a second direction substantially perpendicular to the first direction.

16. The method of claim 9, wherein the leads are separated from the peripheral frame and the at least one support rail by forming the second gaps.

17. A semiconductor package, comprising:
a leadframe comprising a diepad and a first row of leads, wherein at least one lead of the first row of leads is physically separated from the diepad by a gap;
a semiconductor component arranged on the leadframe; and
an encapsulation material encapsulating the leadframe and the semiconductor component, wherein the encapsulation material comprises a bottom surface arranged at a bottom surface of the semiconductor package, a top surface and a side surface extending from the bottom surface to the top surface,
wherein a side surface of at least one lead of the first row of leads is flush with the side surface of the encapsulation material, and
wherein the flush side surface of the at least one lead is covered by an electroplated metal coating.

18. The semiconductor package of claim 17, wherein the bottom surface of the semiconductor package is planar.

19. The semiconductor package of claim 17, wherein the bottom surface of the encapsulation material, a bottom surface of the diepad and a bottom surface of the at least one lead are arranged in a common plane.

20. The semiconductor package of claim 17, wherein the bottom surface of the semiconductor package is free of grooves between a bottom surface of the diepad and a bottom surface of the first row of leads.

21. The semiconductor package of claim 17, wherein the entire side surface of the at least one lead is flush with the side surface of the encapsulation material.

22. The semiconductor package of claim 17, wherein the entire side surface of the at least one lead is covered by the electroplated metal coating.

23. The semiconductor package of claim 17, wherein a thickness of the metal coating is greater than 4 micrometers.

24. The semiconductor package of claim 17, wherein the metal coating is devoid of gold.

25. The semiconductor package of claim 17, wherein:
the leadframe further comprises a portion of a tie bar, and
a side surface of the portion of the tie bar is flush with a side surface of the encapsulation material.

26. The semiconductor package of claim 25, wherein the side surface of the tie bar is uncovered by a metal coating.

27. The semiconductor package of claim 17, wherein the semiconductor package is a flat no-leads package.
